(19) United States
(12) Patent Application Publication
(10) Pub. No.: US 2021/0321526 A1
(43) Pub. Date: Oct. 14, 2021

(54) TECHNOLOGIES FOR SEALED LIQUID COOLING SYSTEM

(71) Applicants: Devdatta Prakash Kulkarni, Portland, OR (US); Maria De La Luz Belmont Velazquez, Zapopan (MX); Andres Ramirez Macias, Zapopan (MX); Sandeep Ahuja, Portland, OR (US); Tejas Shah, Austin, TX (US); Bijoyraj Sahu, Portland, OR (US)

(72) Inventors: Devdatta Prakash Kulkarni, Portland, OR (US); Maria De La Luz Belmont Velazquez, Zapopan (MX); Andres Ramirez Macias, Zapopan (MX); Sandeep Ahuja, Portland, OR (US); Tejas Shah, Austin, TX (US); Bijoyraj Sahu, Portland, OR (US)

(21) Appl. No.: 17/359,342

(22) Filed: Jun. 25, 2021

(51) Int. Cl. H05K 7/20; H05K 5/06; H05K 5/02

(52) U.S. Cl. CPC H05K 7/203; H05K 7/20509; H05K 5/0239; H05K 5/06; H05K 7/20409

(57) ABSTRACT

Techniques for liquid cooling systems are disclosed. In one embodiment, a hermetically sealed container includes an integrated circuit component and a two-phase coolant. As the integrated circuit component generates heat, the coolant boils, rising to a lid of the container. A cold plate mated with the lid absorbs heat from the lid, causing condensation of the coolant on the underside of the lid. The coolant then drips back down towards the integrated circuit component. Other embodiments are disclosed.

### BACKGROUND

Components such as processors dissipate large amounts of heat, which must be removed to prevent the components from overheating. Air cooling by passing air through fins of a heat sink coupled to the component can provide cooling, but air cooling is limited by the relatively low heat capacity of air. Liquid cooling can take advantage of the large heat capacity of water and other liquids relative to air.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is an isometric view of a module with liquid coolant in a sealed container.

FIG. 2 is an exploded isometric view of the module of FIG. 1.

FIG. 3 is an exploded isometric view of the underside of the module of FIG. 1.

FIG. 4 is an isometric view of a system with several modules with liquid coolant in a sealed container.

FIG. 5 is an isometric view of a system with a module with liquid coolant in a sealed container immersed in a liquid coolant.

FIG. 6 is an isometric view of a module with liquid coolant in a sealed container with internal tubes.

FIG. 7 is an exploded isometric view of the module of FIG. 6.

FIG. 8 is a block diagram of an exemplary computing system in which technologies described herein may be implemented.

### DETAILED DESCRIPTION OF THE DRAWINGS

Liquid cooling can move large amounts of heat from components in computing devices such as processors. Liquid coolant directly contacting components such as dies can increase the efficiency of heat transfer to the coolant. However, allowing the dies to be directly exposed to a variety of coolants raises issues with compatibility between the materials used for the die and connected components and the potential coolants used.

In one embodiment disclosed herein, an integrated circuit component 110 is positioned inside of a hermetically sealed container. A liquid coolant is inside the sealed container as well. In use, as the integrated circuit component 110 generates heat, the heat is transferred to the liquid coolant. In the illustrative embodiment, the heat causes the liquid coolant to boil. A lid 104 of the sealed container has a cold plate 126 mated with it. The liquid coolant heated by the integrated circuit component 110 transfers heat to the lid 104 of the container (e.g., by conduction or condensation), and the cold plate 126 absorbs heat from the lid 104.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. The term “coupled,” “connected,” and “associated” may indicate elements electrically, electromagnetically, thermally, and/or physically (e.g., mechanically or chemically) co-operate or interact with each other, and do not exclude the presence of intermediate elements between the coupled, connected, or associated items absent specific contrary language. Terms modified by the word “substantially” include arrangements, orientations, spacings, or positions that vary slightly from the meaning of the unmodified term. For example, surfaces described as being substantially parallel to each other may be off of being parallel with each other by a few degrees.

The description may use the phrases “in an embodiment,” “in embodiments,” “in some embodiments,” and/or “in various embodiments,” each of which may refer to one or more of the same or different embodiments. Furthermore, the terms “comprising,” “including,” “having,” and the like, as used with respect to embodiments of the present disclosure, are synonymous.

Reference is now made to the drawings, wherein similar or same numbers may be used to designate the same or similar parts in different figures. The use of similar or same numbers in different figures does not mean all figures including similar or same numbers constitute a single or same embodiment. In the following description, for purposes of explanation, numerous specific details are set forth in order to provide a thorough understanding thereof. It may be evident, however, that the novel embodiments can be practiced without these specific details. In other instances, well-known structures and devices are shown in block diagram form to facilitate a description thereof. The intention is to cover all modifications, equivalents, and alternatives within the scope of the claims.

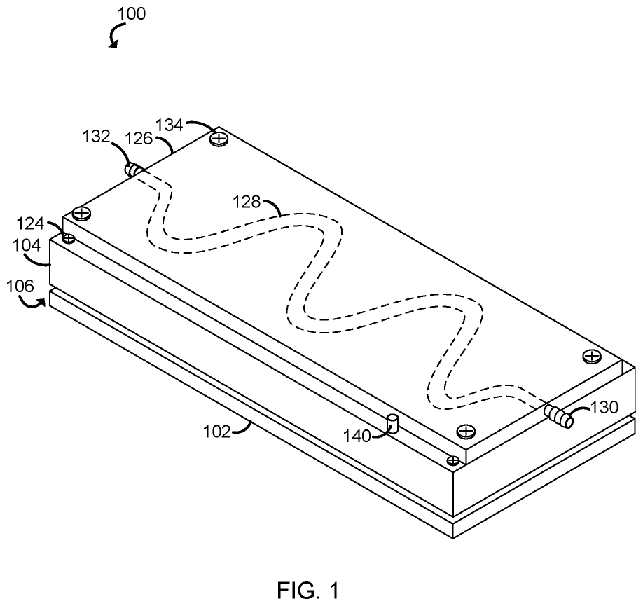

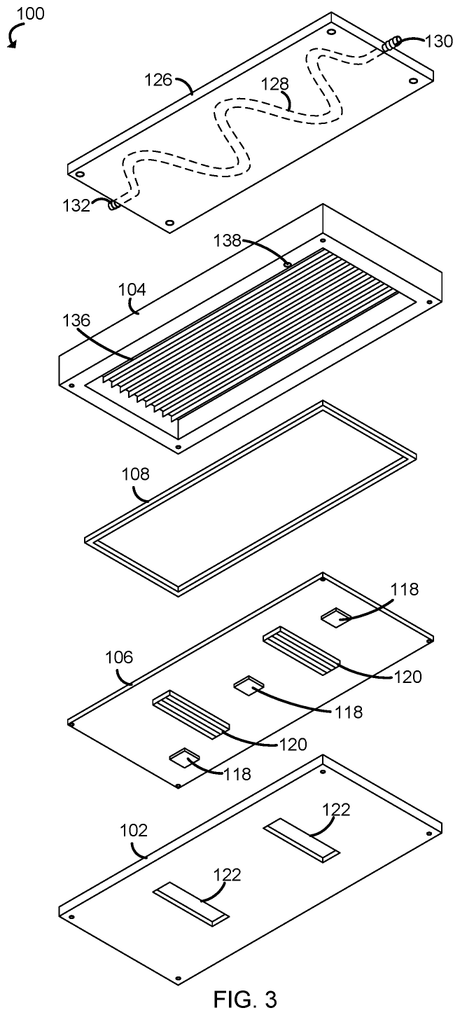

Referring now to FIGS. 1-3, in one embodiment, an illustrative module 100 includes a base 102, a lid 104, and a circuit board 106. In the illustrative embodiment, the lid 104 mates with base 102, with the circuit board 106 positioned between them. The interface between the lid 104 and the circuit board 106 form a hermetic seal. In the illustrative embodiment, a ring seal 108 is positioned at the interface between the lid 104 and the circuit board 106, forming part of the hermetic seal.

The circuit board 106 includes an integrated circuit component 110. The integrated circuit component 110 may include a substrate 112 with, e.g., one or more processor dies 114, one or more high-bandwidth memory (HBM) dies 116, etc. The illustrative circuit board 106 includes a pressure sensor 117 to monitor the pressure inside the container formed by the lid 104 and the circuit board 106. The circuit board 106 may include additional components 118, which may be, e.g., voltage regulators or other power circuitry, communication circuitry, etc.

In the illustrative embodiment, a mezzanine connector 120 is on the bottom side of the circuit board 106. The mezzanine connectors 120 are accessible through a slot 122 on the base 102, allowing the mezzanine connectors 120 to mate with a corresponding connector. The bottom side of the board may also include various components 118.

In the illustrative embodiment, a cold plate 126 is mated with a top surface of the lid 104. The cold plate 126 has a channel 128 defined inside of it. The channel connects an inlet connector 130 to an outlet connector 132.

In use, in the illustrative embodiment, a two-phase coolant is inside the container defined by the lid 104 and the circuit board 106. The two-phase coolant in the liquid phase cools the components of the board, such as the processor dies 114 or HBM dies 116. As it cools the components, the liquid phase may boil into a gas phase. As the illustrative circuit board 106 is positioned below the lid 104, the gas phase rises to the lid 104, where it condenses back to a liquid and drips back to the liquid coolant reservoir. In the illustrative embodiment, the underside of the lid 104 has fins 136 or other structure to increase the surface area of the underside of the lid 104, allowing for more surface area on which the coolant can condense.

In modern integrated circuit components, an integrated heat spreader (IHS) is often used to assist in the transfer of heat from a die to a cold block or other heat sink. A thermal interface material (TIM) is typically used to improve thermal coupling between the die and the IHS. As the TIM and/or IHS may be sensitive to high temperatures need to reflow high-temperature solder, low-temperature solder may be used to, e.g., attach the dies to a substrate, attach the substrate to a circuit board, etc.

In at least some embodiments, the use of a liquid coolant in a hermetically sealed component offers several advantages. The liquid coolant can contact the dies directly, without, e.g., an IHS, TIM, or other objects between the coolant and the dies. Because the coolant can spread out into a large volume or against a large surface area, the heat generated by the components can be cooled with a large cold plate or other heat sink, which can simplify the design of the cold plate or other heat sink. Because there is no IHS or TIM, high-temperature solder such as a tin-silver-copper (Sn—Ag—Cu, or SAC) solder may be used. Use of a SAC solder may offer performance improvements by being less sensitive to thermal fatigue, improved strength, and higher current-carrying capacity. Because the integrated circuit component 110 is in a hermetically sealed container and is only directly exposed to the coolant inside the closed container, a variety of other coolants may be used to cool the lid 104 without any consideration needed for whether the integrated circuit component 110 is compatible with being exposed to the other coolant. That isolation of the integrated circuit component 110 simplifies compatibility concerns both for the manufacturer of the integrated circuit component 110 and the end user. Overall, in at least some embodiments, the techniques disclosed herein can improve cooling efficiency, increase the maximum thermal design power, increase component lifetime, and reduce total cost of ownership.

It should be appreciated that, in the illustrative embodiment, the two-phase coolant circulates due to boiling coolant rising and condensing coolant falling back down. As such, there is no pump or other moving parts that circulate or interact with the two-phase coolant. In the illustrative embodiment, the module 100 does not include any moving parts. As used herein, a micro-scale movement such as a membrane of a pressure sensor 117 is not considered a moving part.

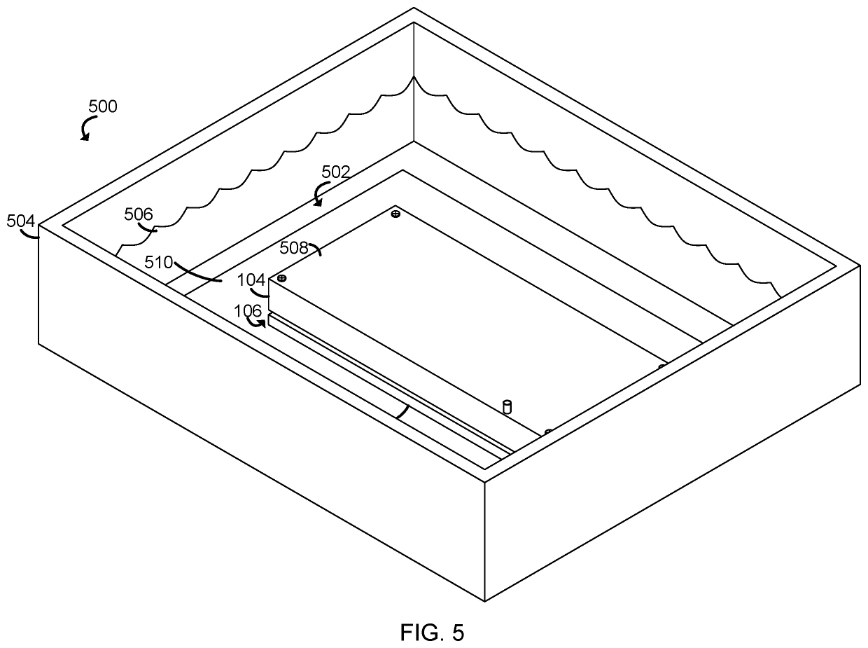

In the illustrative embodiment, the module 100 is embodied as a module compatible with an Open Compute Project (OCP) Accelerator Module (OAM) specification, such as the OAM Design Specification Package version 1.1, dated Jul. 22, 2020. More generally the module 100 may be embodied as any suitable module or form factor and may or may not comply with any suitable technical guidelines. The illustrative module 100 includes one circuit board 106. In other embodiments, a module 100 may include multiple circuit boards. In the illustrative embodiment, the module 100 includes a cold plate 126. In other embodiments, the module 100 may not include a cold plate. For example, the module 100 may be mated with an air-cooled heat sink or with a cold plate that is not considered part of the module 100. In some embodiments, the module 100 may be cooled by immersion cooling (see FIG. 5), in which case a cold plate 126 may not be included.

The base 102 may be made out of any suitable material. In the illustrative embodiment, the base 102 is made out of aluminum. In other embodiments, the base 102 may be made out of, e.g., copper, iron, plastic, etc. In the illustrative embodiment, the base 102 does not form part of the hermetically sealed container. In other embodiments, the base 102 may form part of the hermetically sealed container. For example, in one embodiment, the lid 104 may mate with the base at a hermetic seal, which may include a ring seal 108. In such an embodiment, the circuit board 106 may be enclosed within the hermetic container formed by the lid 104 and the base 102. In such an embodiment, one or more communication and/or power channels may connect from outside the hermetically sealed container to the circuit board 106. For example, mezzanine connectors 120 may pass through a slot 122 in the base 102, and the base 102 may form a hermetic seal with the circuit board 106 around the mezzanine connectors 120. In other embodiments, one or more communication and/or power channels may be provided in another way, such as one or more connectors that pass through the base 102 or lid 104.

The base 102 may have any suitable dimensions. For example, in one embodiment, the base 102 may have a width of about 60 millimeters, a length of about 120 millimeters, and a height of about 5 millimeters. In other embodiments, the base 102 may have any suitable dimensions, such as a length and/or width of 20-200 millimeters and a height of 0.5-50 millimeters.

In the illustrative embodiment, the lid 104 is made out of copper. In other embodiments, the lid 104 may be made out of any other suitable material with a high thermal conductivity, such as aluminum. The lid 104 may have any suitable dimensions. For example, in one embodiment, the lid 104 may have a has a width of about 60 millimeters, a length of about 120 millimeters, and a height of about 20 millimeters. In other embodiments, the lid 104 may have any suitable dimensions, such as a length and/or width of 20-200 millimeters and a height of 0.5-50 millimeters.

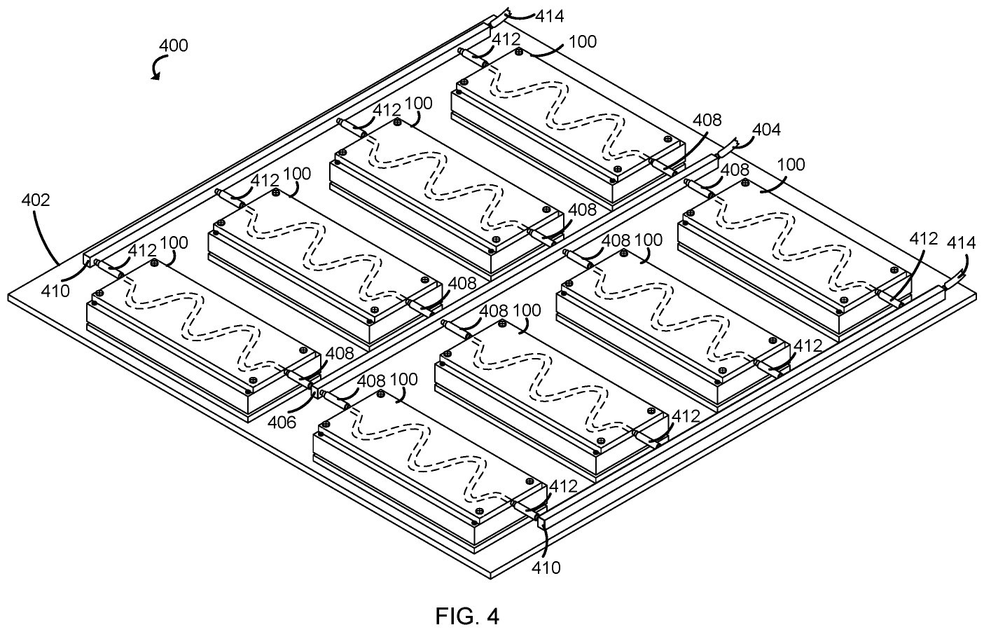

In the illustrative embodiment, the lid 104 is secured in place with one or more fasteners 124. In the illustrative embodiment, fasteners 124 are embodied as screws or bolts. Fasteners 124 may have a spring that applies a downward force on the lid 104. In the illustrative embodiment, the fasteners 124 pass through the circuit board 106 and the base 102 and mate the module 100 with another component of a system, such as a universal base board 402 (see FIG. 4). Additionally or alternatively, in some embodiments, fasteners 124 may mate the lid 104 with the circuit board 106 and/or the base 102. The fasteners 124 can screw directly into threaded holes or may be secured by, e.g., a nut. Additionally or alternatively, the fasteners 124 may be embodied as any other suitable type of fastener, such as a torsion fastener, a spring screw, one or more clips, a land grid array (LGA) loading mechanism, and/or a combination of any suitable types of fasteners. In the illustrative embodiment, the fasteners 124 are removable. In other embodiments, some or all of the fasteners 124 may permanently secure the lid 104 to the circuit board 106, the base 102, and/or any other suitable component. In the illustrative embodiment, the fasteners 124 apply a force on the lid 104 to create the hermetic seal with the circuit board 106. In other embodiments, the hermetic seal may be formed in a different way, such as an adhesive, a braze, a weld, another component applying force to the lid 104, circuit board 106, base 102, etc.

In the illustrative embodiment, the lid 104 includes an opening 138 into which coolant can be supplied. In the illustrative embodiment, an end user may remove a cap 140 in order to add additional coolant. In some embodiments, the liquid coolant may be added at the time of manufacture and cannot be added or removed. In use, the cap 140 seals the opening 138, maintaining the hermetic seal in the container defined by the lid 104 and the circuit board 106. The cap 140 may cover the opening by screwing into threads in the opening, being clamped in place, being secured by an adhesive, etc.

In the illustrative embodiment, the underside of the lid 104 has one or more fins 136 extending downward. The fins 136 increase the surface area for the coolant to condense on. In the illustrative embodiment, the pitch of the fins 136 is about 1 millimeter, and each fin 136 is about 1 millimeter thick and 5 millimeters long. More generally, the pitch of the fins 136 could be, e.g., 0.4-2 millimeters, the thickness of the fins 136 could be, e.g., 0.2-1 millimeters, and the length of the fins 136 can be, e.g., 1-20 millimeters long.

The circuit board 106 may include other components not shown, such as interconnects, other electrical components such as capacitors or resistors, sockets for components such as memory or peripheral cards, connectors for peripherals, etc. In some embodiments, the circuit board 106 may be embodied as a motherboard or mainboard of the module 100. In other embodiments, the circuit board 106 may form or be a part of another component of a computing device, such as a peripheral card, a graphics card, a mezzanine board, a peripheral board, etc. The illustrative circuit board 106 is a fiberglass board made of glass fibers and a resin, such as FR-4. In other embodiments, other types of circuit boards may be used.

In the illustrative embodiment, the integrated circuit component 110 is embodied as a processing unit of a computing device. More generally, as used herein, the term “integrated circuit component” refers to a packaged or unpacked integrated circuit product. A packaged integrated circuit component comprises one or more integrated circuits. In one example, a packaged integrated circuit component contains one or more processor units and a land grid array (LGA) or pin grid array (PGA) on an exterior surface of the package. In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component or type of component described or referenced herein, such as a processor unit (e.g., system-on-a-chip (SoC), processor cores, graphics processor unit (GPU), accelerator), I/O controller, chipset processor, memory, network interface controller, or a three-dimensional integrated circuit (3D IC) face-to-face-based packaging chip such as an Intel® Foveros chip. In one embodiment, the integrated circuit component 110 is a processor unit, such as a single-core processor, a multi-core processor, a desktop processor, a server processor, a data processing unit, a central processing unit, a graphics processing unit, an accelerator unit, an application-specific integrated circuit (ASIC), a field-programmable gate array (FPGA), etc. The processor unit may include an integrated memory, such as a high-bandwidth memory 116. The integrated circuit component 110 may include one or more chips integrated into a multi-chip package (MCP). For example, in one embodiment, the integrated circuit component 110 may include one or more processor chips 114 and one or more memory chips 116.

The illustrative integrated circuit component 110 does not include an integrated heat spreader. However, in some embodiments, the integrated circuit component 110 may include an integrated heat spreader.

The illustrative substrate 112 includes interconnects to connect electrical paths of the dies of the integrated circuit component 110 both to each other and to external connections, such as to pins of a socket or solder bumps. In some embodiments, the substrate 112 may include embedded multi-die interconnect bridge (EMIB) technology. In the illustrative embodiment, the substrate 112 includes a land grid array of pads. Each pad may be any suitable material, such as gold, copper, silver, gold-plated copper, etc. Additionally or alternatively, in some embodiments, the substrate 112 may include a pin grid array with one or more pins that mate with a corresponding pin socket in a processor socket or a ball grid array. The substrate 112 may include one or more additional components, such as a capacitor, voltage regulator, etc. The illustrative substrate 112 is a fiberglass board made of glass fibers and a resin, such as FR-4. In other embodiments, the substrate 112 may be embodied as any suitable circuit board, a silicon chip, and/or the like.

The illustrative substrate 112 has a width of about 30 millimeters, a length of about 50 millimeters, and a height of about 3 millimeters. In other embodiments, the substrate 112 may have any suitable dimensions, such as a length and/or width of 1-200 millimeters and a height of 0.5-20 millimeters.

The various dies of the integrated circuit component 110 may generate any suitable amount of heat. For example, in one embodiment, the integrated circuit component 110 may generate up to 500 Watts of power. The power may be split between the various dies in any suitable manner. The integrated circuit component 110 may be maintained at less than any suitable temperature, such as 30-150° C.

The pressure sensor 117 may sense the pressure inside the hermetically sealed container. The pressure sensor 117 may be, e.g., a piezoresistive strain gauge, a capacitive pressure sensor, an electromagnetic pressure sensor, and/or the like. The pressure sensor 117 may be used to ensure that pressure inside the hermetically sealed container does not increase past a threshold. The circuit board 106 and/or integrated circuit component 110 may include one or more circuits configured to monitor the pressure and, if the pressure increases past a threshold, decrease power used by the module 100. For example, in one embodiment, if the pressure increases past 15 pounds per square inch (psi), power of the module 100 may be reduced. In other embodiments, the threshold may be set to any suitable amount, such as 10-50 psi. In some embodiments, the module 100 may include a pressure release valve to release pressure if the pressure is too high. The pressure sensor 117 may report the sensed pressure to the integrated circuit component 110, another component 118, a server computer, and/or any other suitable device.

The sensed pressure can also be used to monitor the performance of the coolant. For example, if a temperature of the integrated circuit component 110 (as measured, e.g., by a temperature-sensing component internal or external to the integrated circuit component 110) is high but the sensed pressure inside the hermetically sealed container is low, that may indicate that there is insufficient coolant in the hermetically sealed container.

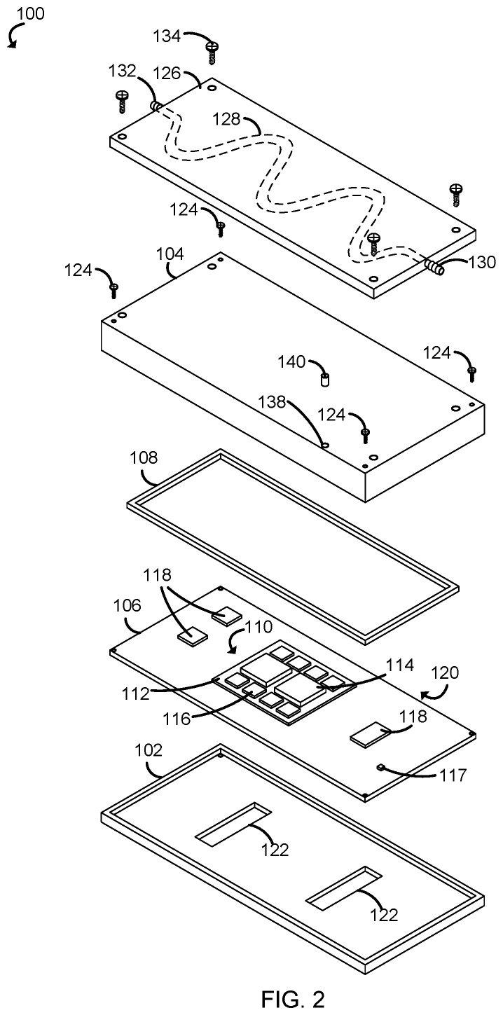

The additional components 118 on the circuit board 106 may be any suitable components, such as voltage regulators. As the components 118 shown in FIG. 2 are inside the container formed by the lid 104 and the circuit board 106, the components 118 will be cooled by the liquid coolant as well. In embodiments in which the underside of the circuit board 106 is in contact with the liquid coolant (such as embodiments in which the lid 104 and the base 102 form the hermetically sealed container), components on the underside of the circuit board 106 can be cooled by the liquid as well. In one embodiment, voltage regulators 118 may be positioned on the underside of the circuit board 106, close to the integrated circuit component 110, leading to less resistive losses between the voltage regulators 118 and the integrated circuit component.

The ring seal 108 may be made of any suitable material that facilitates the ring seal 108 forming a hermetic seal. For example, the ring seal 108 may be made of ethylene propylene diene monomer (EPDM), rubber, silicone, plastic, etc. In some embodiments, the ring seal 108 may have a cross-section shaped like an “0.” In other embodiments, the ring seal 108 may have a cross-section with a different shape.

In the illustrative embodiment, the cold plate 126 is made from a high-thermal-conductivity material, such as copper, aluminum, or another material with a thermal conductivity greater than 100 W/(m×K). In some embodiments, the cold plate 126 may be made of more than one material. For example, in one embodiment, the cold plate 126 may be an aluminum body with a copper tube 128 carrying coolant embedded in the aluminum body. It should be appreciated that the cold plate 126 is not necessarily cold. For example, when the module 100 is assembled but not in use, the cold plate 126 may be at room temperature (and the same temperature as, e.g., the integrated circuit component 110). In use, the cold plate 126 may have coolant flowing through it that is colder than, e.g., the integrated circuit component 110 but not colder than ambient temperatures. Of course, in some embodiments, the coolant flowing through it may be colder than ambient temperatures.

The cold plate 126 may have any suitable dimensions. For example, the cold plate 126 may have a width of 10-250 millimeters, a length of 10-250 millimeters, and/or a height of 3-100 millimeters. In the illustrative embodiment, the cold plate 126 has a width of about 50 millimeters, a length of about 120 millimeters, and a height of about 10 millimeters.

The inlet connector 130 and outlet connector 132 may be any suitable connectors, such as a barbed fitting, a push-to-connect fitting, a fitting with a tube held in place using a clip or other retainer, etc. The inlet connector 130 and/or outlet connector 132 may be any suitable material, such as aluminum, copper, plastic, polyvinyl chloride (PVC), etc. In the illustrative embodiment, liquid coolant can be passed in either direction through the channel 128 (that is, from the inlet connector 130 to the outlet connector 132 or from the outlet connector 132 to the inlet connector 130. In some embodiments, there may be a thermal interface material (TIM) between the cold plate 126 and the lid 104.

The coolant passing through the cold plate 126 may be any suitable fluid or mix of fluids, such as such as water, deionized water, alcohol, glycol, and/or any other suitable fluid or mix of fluids. As the coolant passing through the cold plate 126 is not in contact with the components on the circuit board 106, the coolant passing through the cold plate 126 does not need to be compatible with the components on the circuit board 106.

In the illustrative embodiment, the coolant in the hermetically sealed container is a dielectric coolant that is compatible with the circuit board 106, integrated circuit component 110, other components 118, etc. The illustrative coolant may be non-flammable and have a global warming potential less than one relative to carbon dioxide.

In the illustrative embodiment, a two-phase coolant is in the hermetically sealed container. The two-phase coolant may have any suitable boiling point, such as 30-80° C. As used herein, a two-phase coolant refers to a coolant whose boiling point is within the operational temperature range of the integrated circuit component 110. For example, the two-phase coolant may be, e.g., 3M™ FC-3284, 3M™ FC-72, Solvay Galden® HT-55, 3M™ Novec™ 7000, 3M™ Novec™ 7100, 3M™ Novec™ 649, etc.

In the illustrative embodiment, the two-phase coolant does not fully fill the hermetically sealed container. For example, an inert gas such as nitrogen, helium, argon, etc., may partially fill the hermetically sealed container. In the illustrative embodiment, the container is partially filled with the two-phase coolant at a liquid temperature (e.g., at room temperature), with an inert gas filling the container before hermetic sealing. In use, the temperature of the two-phase coolant increases until its boiling point, at which point the two-phase coolant begins to boil. As the two-phase coolant boils, the pressure inside the hermetically sealed container may increase to, e.g., 10 pounds per square inch (psi) above ambient pressure. The pressure sensor 117 may be used to ensure that the pressure inside the hermetically sealed container does not increase beyond a threshold.

In the illustrative embodiment, the amount of coolant in the container defined by the lid 104 and the circuit board 106 is enough to cover each component. As such, each component is cooled by the liquid coolant. In some embodiments, some of the components may rise above the level of the liquid coolant. For example, a low-power component that does not require significant cooling may rise above a level of the liquid coolant.

In other embodiments, a single-phase coolant may be in the hermetically sealed container. As used herein, a single-phase coolant refers to a coolant whose boiling point is above the operational temperature range of the integrated circuit component 110. For example, in one embodiment, the operational temperature range of the integrated circuit component 110 may be, e.g., 60-100° C., and a single-phase coolant with a boiling point of 120-500° C. may be used. In embodiments in which a single-phase coolant is used, the fins 136 of the lid 104 may extend into the single-phase coolant in order to facilitate heat transfer. In some embodiments, the heat transfer ability of a single-phase coolant may be relatively low compared to a two-phase coolant, and use of a single-phase coolant may be better suited to low-power applications.

Referring now to FIG. 4, in one embodiment, a system 400 includes a universal base board (UBB) 402 on which multiple modules 100 are positioned. Each module 100 may connect to the UBB 402 through a mezzanine connector 120. The UBB 402 may include other components not shown, such as interconnects, other electrical components such as capacitors or resistors, sockets for components such as memory or peripheral cards, connectors for peripherals, etc. Each cold plate 126 of each module 100 is connected to an inlet manifold 406 by an inlet tube 408, and is connected to an outlet manifold 410 by an outlet tube 412. In the illustrative embodiment, coolant flows from a manifold inlet tube 404 to the inlet manifold 406, through the cold plate 126 of each module 100, and into the outlet manifold 410 and manifold outlet tube 414. The coolant may be cooled and then returned to the inlet manifold 406. The coolant may be connected to a radiator, a heat exchanger, a chiller, or other cooling mechanisms to cool the coolant before it returns to the inlet manifold 406. In some embodiments, a single cold plate may be coupled to more than one module 100. For example, one cold plate may be used to cool all of the modules 100 shown in FIG. 4.

Any of the tubes disclosed herein may be any suitable material, such as PVC, copper, aluminum, etc. In the illustrative embodiment, the tubes 408, 412 are PVC.

Referring now to FIG. 5, in one embodiment, a system 500 includes a module 502 that is placed in a container 504. The module 502 is immersed in a bath of liquid coolant 506. The liquid coolant 506 may be a single-phase or two-phase coolant. The liquid coolant 506 may be cooled by, e.g., being pumped through a radiator, a heat exchanger, a chiller, condenser, or other cooling mechanisms to cool the coolant before it returns to the container 504.

The module 502 may be similar to the module 100, and may include a lid 104, a base 102, and a circuit board 106 described in more detail above, a description of which will not be repeated in the interest of clarity. In some embodiments, the top surface of the lid may have a boiling-enhancement coating 508 on it to facilitate boiling of the liquid coolant 506.

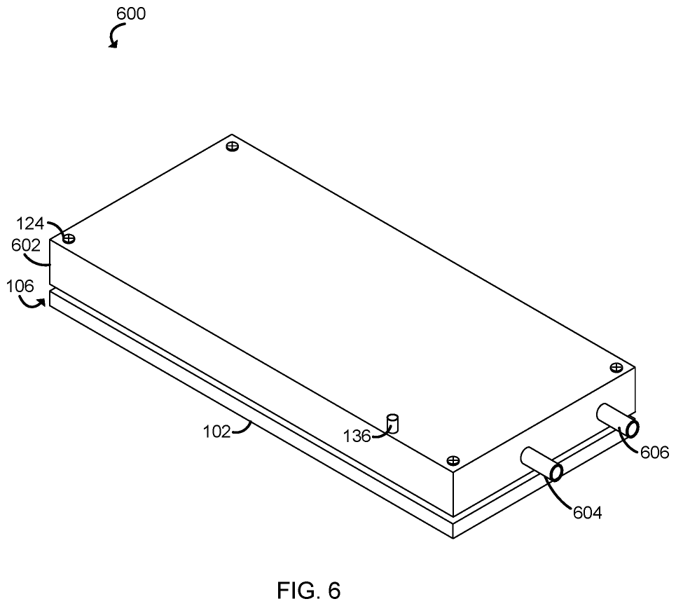

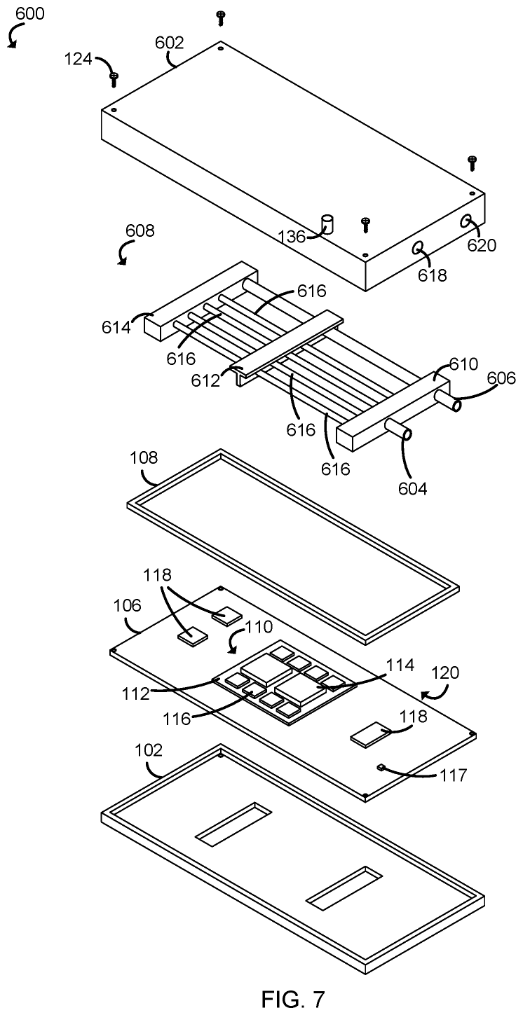

Referring now to FIGS. 6 & 7, in one embodiment, a module 600 has a lid 602 with an inlet tube 604 and an outlet tube 606. A tube assembly 608 is positioned inside a hermetically sealed container formed by the lid 602 and the circuit board 106. As shown in FIG. 7, the inlet tube 604 is connected to a manifold 610 that splits the incoming coolant to one or more tubes 616. The tubes 616 pass through a structural support 612 to a manifold 614, which recombines the coolant flowing through the tubes 616 to the outlet tube 606. In use, the tubes 616 provide a cool surface for the two-phase coolant in the module 600 to condense onto.

The lid 602 may be similar to the lid 104, with the addition of an inlet hole 618 and an outlet hole 620 for the inlet tube 604 and the outlet tube 606. In some embodiments, the lid 602 may include an inlet connector and outlet connector, similar to the cold plate 126. The various components of the module 600, such as the circuit board 106, the base 102, the ring seal 108, etc., may be similar to or the same as the corresponding component of the module 100. As such, in the interest of clarity, a description of those components will not be repeated.

In some embodiments, coolant may be supplied to a module through an inlet tube, similar to the inlet tube 604 shown in FIG. 7. The liquid may pass through jets inside the module that are directed to the integrated circuit component or other components to be cooled. The jets can be present in any suitable number, size, angle, position (including the underside of a circuit board), etc. The liquid coolant can exit from such a module through an outlet tube similar to the outlet tube 606 shown in FIG. 7.

The technologies described herein can be performed by or implemented in any of a variety of computing systems, including mobile computing systems (e.g., smartphones, handheld computers, tablet computers, laptop computers, portable gaming consoles, 2-in-1 convertible computers, portable all-in-one computers), non-mobile computing systems (e.g., desktop computers, servers, workstations, stationary gaming consoles, set-top boxes, smart televisions, rack-level computing solutions (e.g., blades, trays, sleds)), and embedded computing systems (e.g., computing systems that are part of a vehicle, smart home appliance, consumer electronics product or equipment, manufacturing equipment). As used herein, the term “computing system” includes computing devices and includes systems comprising multiple discrete physical components. In some embodiments, the computing systems are located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge or micro data center (e.g., a data center, typically having a smaller footprint than other data center types, located close to the geographic area that it serves).

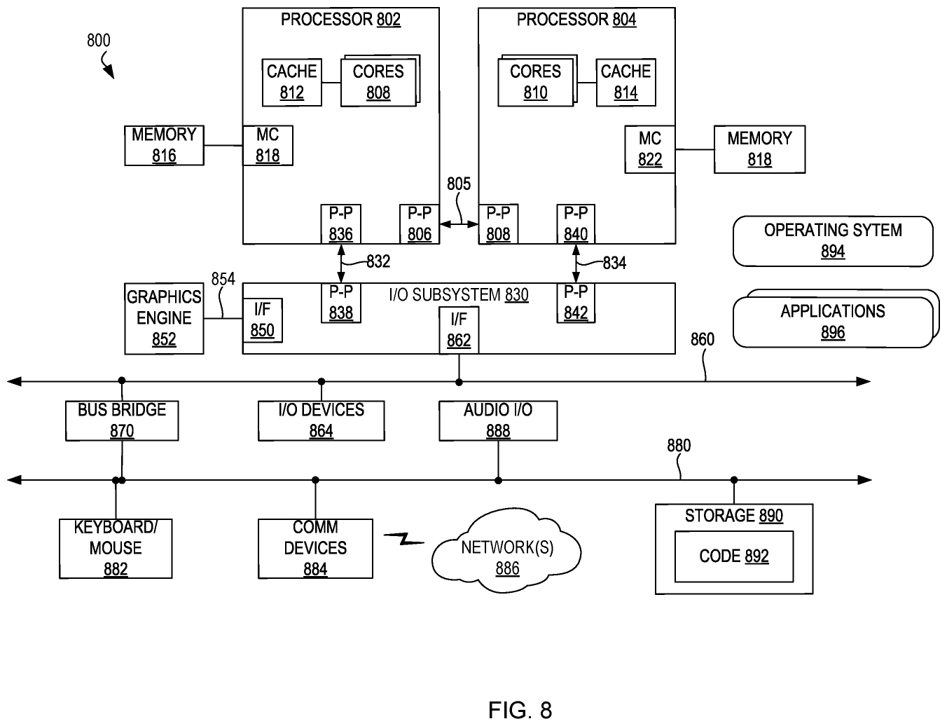

FIG. 8 is a block diagram of a second example computing system in which technologies described herein may be implemented. Generally, components shown in FIG. 8 can communicate with other shown components, although not all connections are shown, for ease of illustration. The computing system 800 is a multiprocessor system comprising a first processor unit 802 and a second processor unit 804 comprising point-to-point (P-P) interconnects. A point-to-point (P-P) interface 806 of the processor unit 802 is coupled to a point-to-point interface 807 of the processor unit 804 via a point-to-point interconnection 805. It is to be understood that any or all of the point-to-point interconnects illustrated in FIG. 8 can be alternatively implemented as a multi-drop bus, and that any or all buses illustrated in FIG. 8 could be replaced by point-to-point interconnects.

The processor units 802 and 804 comprise multiple processor cores. Processor unit 802 comprises processor cores 808 and processor unit 804 comprises processor cores 810. Processor cores 808 and 810 can execute computer-executable instructions.

Processor units 802 and 804 further comprise cache memories 812 and 814, respectively. The cache memories 812 and 814 can store data (e.g., instructions) utilized by one or more components of the processor units 802 and 804, such as the processor cores 808 and 810. The cache memories 812 and 814 can be part of a memory hierarchy for the computing system 800. For example, the cache memories 812 can locally store data that is also stored in a memory 816 to allow for faster access to the data by the processor unit 802. In some embodiments, the cache memories 812 and 814 can comprise multiple cache levels, such as level 1 (L1), level 2 (L2), level 3 (L3), level 4 (L4), and/or other caches or cache levels, such as a last level cache (LLC). Some of these cache memories (e.g., L2, L3, L4, LLC) can be shared among multiple cores in a processor unit. One or more of the higher levels of cache levels (the smaller and faster caches) in the memory hierarchy can be located on the same integrated circuit die as a processor core and one or more of the lower cache levels (the larger and slower caches) can be located on an integrated circuit dies that are physically separate from the processor core integrated circuit dies.

Although the computing system 800 is shown with two processor units, the computing system 800 can comprise any number of processor units. Further, a processor unit can comprise any number of processor cores. A processor unit can take various forms such as a central processing unit (CPU), a graphics processing unit (GPU), general-purpose GPU (GPGPU), accelerated processing unit (APU), field-programmable gate array (FPGA), neural network processing unit (NPU), data processor unit (DPU), accelerator (e.g., graphics accelerator, digital signal processor (DSP), compression accelerator, artificial intelligence (AI) accelerator), controller, or other types of processing units. As such, the processor unit can be referred to as an XPU (or xPU). Further, a processor unit can comprise one or more of these various types of processing units. In some embodiments, the computing system comprises one processor unit with multiple cores, and in other embodiments, the computing system comprises a single processor unit with a single core. As used herein, the terms “processor unit” and “processing unit” can refer to any processor, processor core, component, module, engine, circuitry, or any other processing element described or referenced herein.

In some embodiments, the computing system 800 can comprise one or more processor units that are heterogeneous or asymmetric to another processor unit in the computing system. There can be a variety of differences between the processing units in a system in terms of a spectrum of metrics of merit including architectural, microarchitectural, thermal, power consumption characteristics, and the like. These differences can effectively manifest themselves as asymmetry and heterogeneity among the processor units in a system.

The processor units 802 and 804 can be located in a single integrated circuit component (such as a multi-chip package (MCP) or multi-chip module (MCM)) or they can be located in separate integrated circuit components. An integrated circuit component comprising one or more processor units can comprise additional components, such as embedded DRAM, stacked high bandwidth memory (HBM), shared cache memories (e.g., L3, L4, LLC), input/output (I/O) controllers, or memory controllers. Any of the additional components can be located on the same integrated circuit die as a processor unit, or on one or more integrated circuit dies separate from the integrated circuit dies comprising the processor units. In some embodiments, these separate integrated circuit dies can be referred to as “chiplets”. In some embodiments where there is heterogeneity or asymmetry among processor units in a computing system, the heterogeneity or asymmetric can be among processor units located in the same integrated circuit component.

Processor units 802 and 804 further comprise memory controller logic (MC) 820 and 822. As shown in FIG. 8, MCs 820 and 822 control memories 816 and 818 coupled to the processor units 802 and 804, respectively. The memories 816 and 818 can comprise various types of volatile memory (e.g., dynamic random-access memory (DRAM), static random-access memory (SRAM)) and/or non-volatile memory (e.g., flash memory, chalcogenide-based phase-change non-volatile memories), and comprise one or more layers of the memory hierarchy of the computing system. While MCs 820 and 822 are illustrated as being integrated into the processor units 802 and 804, in alternative embodiments, the MCs can be external to a processor unit.

Processor units 802 and 804 are coupled to an Input/Output (I/O) subsystem 830 via point-to-point interconnections 832 and 834. The point-to-point interconnection 832 connects a point-to-point interface 836 of the processor unit 802 with a point-to-point interface 838 of the I/O subsystem 830, and the point-to-point interconnection 834 connects a point-to-point interface 840 of the processor unit 804 with a point-to-point interface 842 of the I/O subsystem 830. Input/Output subsystem 830 further includes an interface 850 to couple the I/O subsystem 830 to a graphics engine 852. The I/O subsystem 830 and the graphics engine 852 are coupled via a bus 854.

The Input/Output subsystem 830 is further coupled to a first bus 860 via an interface 862. The first bus 860 can be a Peripheral Component Interconnect Express (PCIe) bus or any other type of bus. Various I/O devices 864 can be coupled to the first bus 860. A bus bridge 870 can couple the first bus 860 to a second bus 880. In some embodiments, the second bus 880 can be a low pin count (LPC) bus. Various devices can be coupled to the second bus 880 including, for example, a keyboard/mouse 882, audio I/O devices 888, and a storage device 890, such as a hard disk drive, solid-state drive, or another storage device for storing computer-executable instructions (code) 892 or data. The code 892 can comprise computer-executable instructions for performing methods described herein. Additional components that can be coupled to the second bus 880 include communication device(s) 884, which can provide for communication between the computing system 800 and one or more wired or wireless networks 886 (e.g. Wi-Fi, cellular, or satellite networks) via one or more wired or wireless communication links (e.g., wire, cable, Ethernet connection, radio-frequency (RF) channel, infrared channel, Wi-Fi channel) using one or more communication standards (e.g., IEEE 802.11 standard and its supplements).

In embodiments where the communication devices 884 support wireless communication, the communication devices 884 can comprise wireless communication components coupled to one or more antennas to support communication between the computing system 800 and external devices. The wireless communication components can support various wireless communication protocols and technologies such as Near Field Communication (NFC), IEEE 802.11 (Wi-Fi) variants, WiMax, Bluetooth, Zigbee, 4G Long Term Evolution (LTE), Code Division Multiplexing Access (CDMA), Universal Mobile Telecommunication System (UMTS) and Global System for Mobile Telecommunication (GSM), and 5G broadband cellular technologies. In addition, the wireless modems can support communication with one or more cellular networks for data and voice communications within a single cellular network, between cellular networks, or between the computing system and a public switched telephone network (PSTN).

The system 800 can comprise removable memory such as flash memory cards (e.g., SD (Secure Digital) cards), memory sticks, Subscriber Identity Module (SIM) cards). The memory in system 800 (including caches 812 and 814, memories 816 and 818, and storage device 890) can store data and/or computer-executable instructions for executing an operating system 894 and application programs 896. Example data includes web pages, text messages, images, sound files, and video data to be sent to and/or received from one or more network servers or other devices by the system 800 via the one or more wired or wireless networks 886, or for use by the system 800. The system 800 can also have access to external memory or storage (not shown) such as external hard drives or cloud-based storage.

The operating system 894 can control the allocation and usage of the components illustrated in FIG. 8 and support the one or more application programs 896. The application programs 896 can include common computing system applications (e.g., email applications, calendars, contact managers, web browsers, messaging applications) as well as other computing applications.

The computing system 800 can support various additional input devices, such as a touchscreen, microphone, monoscopic camera, stereoscopic camera, trackball, touchpad, trackpad, proximity sensor, light sensor, electrocardiogram (ECG) sensor, PPG (photoplethysmogram) sensor, galvanic skin response sensor, and one or more output devices, such as one or more speakers or displays. Other possible input and output devices include piezoelectric and other haptic I/O devices. Any of the input or output devices can be internal to, external to, or removably attachable with the system 800. External input and output devices can communicate with the system 800 via wired or wireless connections.

In addition, the computing system 800 can provide one or more natural user interfaces (NUIs). For example, the operating system 894 or applications 896 can comprise speech recognition logic as part of a voice user interface that allows a user to operate the system 800 via voice commands. Further, the computing system 800 can comprise input devices and logic that allows a user to interact with computing the system 800 via body, hand, or face gestures.

The system 800 can further include at least one input/output port comprising physical connectors (e.g., USB, IEEE 1394 (FireWire), Ethernet, RS-232), a power supply (e.g., battery), a global satellite navigation system (GNSS) receiver (e.g., GPS receiver); a gyroscope; an accelerometer; and/or a compass. A GNSS receiver can be coupled to a GNSS antenna. The computing system 800 can further comprise one or more additional antennas coupled to one or more additional receivers, transmitters, and/or transceivers to enable additional functions.

It is to be understood that FIG. 8 illustrates only one example computing system architecture. Computing systems based on alternative architectures can be used to implement technologies described herein. For example, instead of the processor units 802 and 804 and the graphics engine 852 being located on discrete integrated circuits, a computing system can comprise an SoC (system-on-a-chip) integrated circuit incorporating multiple processors, a graphics engine, and additional components. Further, a computing system can connect its constituent component via bus or point-to-point configurations different from that shown in FIG. 8. Moreover, the illustrated components in FIG. 8 are not required or all-inclusive, as shown components can be removed and other components added in alternative embodiments.

As used in this application and in the claims, a list of items joined by the term “and/or” can mean any combination of the listed items. For example, the phrase “A, B and/or C” can mean A; B; C; A and B; A and C; B and C; or A, B and C. As used in this application and in the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and in the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

### Examples

Illustrative examples of the technologies disclosed herein are provided below. An embodiment of the technologies may include any one or more, and any combination of, the examples described below.

Example 1 includes a system comprising a hermetically sealed container; an integrated circuit component positioned inside the hermetically sealed container; and a liquid coolant inside the hermetically sealed container.

Example 2 includes the subject matter of Example 1, and wherein the liquid coolant is a two-phase liquid coolant.

Example 3 includes the subject matter of any of Examples 1 and 2, and wherein the liquid coolant has a boiling point between 30 degrees Celsius and 80 degrees Celsius.

Example 4 includes the subject matter of any of Examples 1-3, and wherein the hermetically sealed container comprises a lid and a circuit board, wherein the integrated circuit component is mated with the circuit board, wherein the lid forms a hermetic seal with the circuit board.

Example 5 includes the subject matter of any of Examples 1-4, and wherein the lid comprises a plurality of fins inside the hermetically sealed container, wherein individual fins of the plurality extend from an inside surface of the lid towards the circuit board.

Example 6 includes the subject matter of any of Examples 1-5, and wherein the liquid coolant is a single-phase liquid coolant, wherein individual fins of the plurality of fins extend into the single-phase liquid coolant.

Example 7 includes the subject matter of any of Examples 1-6, and wherein one or more dies of the integrated circuit component are mated to a substrate of the integrated circuit component with tin-silver-copper high-temperature solder.

Example 8 includes the subject matter of any of Examples 1-7, and wherein the circuit board comprises one or more mezzanine connectors on a side of the circuit board opposite the integrated circuit component, wherein the one or more mezzanine connectors are mated with a corresponding connector of a universal baseboard.

Example 9 includes the subject matter of any of Examples 1-8, and wherein the integrated circuit component comprises an accelerator, wherein the hermetically sealed container is an accelerator module.

Example 10 includes the subject matter of any of Examples 1-9, and further including a ring seal positioned between the lid and the circuit board.

Example 11 includes the subject matter of any of Examples 1-10, and further including one or more tubes extending into the hermetically sealed container to carry a second liquid coolant different from the liquid coolant through the hermetically sealed container.

Example 12 includes the subject matter of any of Examples 1-11, and wherein the integrated circuit component comprises one or more dies, wherein individual dies of the one or more dies are in direct contact with the liquid coolant.

Example 13 includes the subject matter of any of Examples 1-12, and wherein the hermetically sealed container is immersed in a second liquid coolant different from the liquid coolant.

Example 14 includes the subject matter of any of Examples 1-13, and further including a boiling-enhancement coating on an outside surface of the hermetically sealed container.

Example 15 includes the subject matter of any of Examples 1-14, and further including a cold plate mated with a lid of the hermetically sealed container.

Example 16 includes the subject matter of any of Examples 1-15, and wherein the hermetically sealed container contains a circuit board comprising a first side and a second side, wherein the integrated circuit component is mated to the first side of the circuit board, further comprising a voltage regulator mated to the second side of the circuit board, wherein the integrated circuit component and the voltage regulator are in contact with the liquid coolant.

Example 17 includes the subject matter of any of Examples 1-16, and wherein the hermetically sealed container does not include any moving parts.

Example 18 includes a system comprising a lid of a hermetically sealed container, the hermetically sealed container to contain a circuit board comprising an integrated circuit component, the lid comprising an inside surface of the hermetically sealed container; and a base of a hermetically sealed container, the base to mate with the lid to form a hermetic seal, wherein the lid comprises a plurality of fins, wherein individual fins of the plurality extend from an inside surface of the lid.

Example 19 includes the subject matter of Example 18, and wherein the base is mated with the lid to form the hermetic seal.

Example 20 includes the subject matter of any of Examples 18 and 19, and further including the integrated circuit component positioned inside the hermetically sealed container.

Example 21 includes the subject matter of any of Examples 18-20, and further including a two-phase liquid coolant in the hermetically sealed container.

Example 22 includes the subject matter of any of Examples 18-21, and wherein the two-phase liquid coolant has a boiling point between 30 degrees Celsius and 80 degrees Celsius.

Example 23 includes the subject matter of any of Examples 18-22, and further including a ring seal positioned between the lid and the base.

Example 24 includes the subject matter of any of Examples 18-23, and further including a single-phase liquid coolant in the hermetically sealed container, wherein individual fins of the plurality of fins extend into the single-phase liquid coolant.

Example 25 includes the subject matter of any of Examples 18-24, and wherein one or more dies of the integrated circuit component are mated to a substrate of the integrated circuit component with tin-silver-copper high-temperature solder.

Example 26 includes the subject matter of any of Examples 18-25, and wherein the circuit board comprises one or more mezzanine connectors on a side of the circuit board opposite the integrated circuit component, wherein the one or more mezzanine connectors are mated with a corresponding connector of a universal baseboard through one or more slots in the base.

Example 27 includes the subject matter of any of Examples 18-26, and wherein the integrated circuit component comprises an accelerator, wherein the hermetically sealed container is an accelerator module.

Example 28 includes the subject matter of any of Examples 18-27, and further including one or more tubes extending into the hermetically sealed container to carry a second liquid coolant different from the liquid coolant through the hermetically sealed container.

Example 29 includes the subject matter of any of Examples 18-28, and wherein the integrated circuit component comprises one or more dies, wherein individual dies of the one or more dies are in direct contact with the liquid coolant.

Example 30 includes the subject matter of any of Examples 18-29, and wherein the hermetically sealed container is immersed in a second liquid coolant different from the liquid coolant.

Example 31 includes the subject matter of any of Examples 18-30, and further including a boiling-enhancement coating on an outside surface of the hermetically sealed container.

Example 32 includes the subject matter of any of Examples 18-31, and wherein the hermetically sealed container contains a circuit board comprising a first side and a second side, wherein the integrated circuit component is mated to the first side of the circuit board, further comprising a voltage regulator mated to the second side of the circuit board, wherein the integrated circuit component and the voltage regulator are in contact with a liquid coolant inside the hermetically sealed container.

Example 33 includes the subject matter of any of Examples 18-32, and wherein the hermetically sealed container does not include any moving parts.

Example 34 includes the subject matter of any of Examples 18-33, and further including a cold plate mated with the lid.

Example 35 includes a system comprising means for transferring heat from a integrated circuit component inside a hermetically sealed container to a lid of the hermetically sealed container; and means for transferring heat from a lid of the hermetically sealed container.

Example 36 includes the subject matter of Example 35, and wherein the means for transferring heat from the integrated circuit component comprise a two-phase coolant.

Example 37 includes the subject matter of any of Examples 35 and 36, and wherein the means for transferring heat from the lid of the hermetically sealed container comprises an immersion bath of a coolant different.

Example 38 includes the subject matter of any of Examples 35-37, and wherein the means for transferring heat from the lid of the hermetically sealed container comprises a cold plate.

1. A system comprising:
a hermetically sealed container;
an integrated circuit component positioned inside the hermetically sealed container; and
a liquid coolant inside the hermetically sealed container.

2. The system of claim 1, wherein the liquid coolant is a two-phase liquid coolant.

3. The system of claim 2, wherein the liquid coolant has a boiling point between 30 degrees Celsius and 80 degrees Celsius.

4. The system of claim 1, wherein the hermetically sealed container comprises a lid and a circuit board,
wherein the integrated circuit component is mated with the circuit board,
wherein the lid forms a hermetic seal with the circuit board.

5. The system of claim 4, wherein the lid comprises a plurality of fins inside the hermetically sealed container, wherein individual fins of the plurality extend from an inside surface of the lid towards the circuit board.

6. The system of claim 5, wherein the liquid coolant is a single-phase liquid coolant, wherein individual fins of the plurality of fins extend into the single-phase liquid coolant.

7. The system of claim 4, wherein one or more dies of the integrated circuit component are mated to a substrate of the integrated circuit with tin-silver-copper high-temperature solder.

8. The system of claim 4, wherein the circuit board comprises one or more mezzanine connectors on a side of the circuit board opposite the integrated circuit component,
wherein the one or more mezzanine connectors are mated with a corresponding connector of a universal baseboard.

9. The system of claim 4, wherein the integrated circuit component comprises an accelerator, wherein the hermetically sealed container is an accelerator module.

10. The system of claim 4, further comprising a ring seal positioned between the lid and the circuit board.

11. The system of claim 1, further comprising one or more tubes extending into the hermetically sealed container to carry a second liquid coolant different from the liquid coolant through the hermetically sealed container.

12. The system of claim 1, wherein the integrated circuit component comprises one or more dies, wherein individual dies of the one or more dies are in direct contact with the liquid coolant.

13. The system of claim 1, wherein the hermetically sealed container is immersed in a second liquid coolant different from the liquid coolant.

14. The system of claim 13, further comprising a boiling-enhancement coating on an outside surface of the hermetically sealed container.

15. The system of claim 1, further comprising a cold plate mated with a lid of the hermetically sealed container.

16. The system of claim 1, wherein the hermetically sealed container contains a circuit board comprising a first side and a second side,
wherein the integrated circuit component is mated to the first side of the circuit board,
further comprising a voltage regulator mated to the second side of the circuit board,
wherein the integrated circuit component and the voltage regulator are in contact with the liquid coolant.

17. The system of claim 1, wherein the hermetically sealed container does not include any moving parts.

18. A system comprising:
a lid of a hermetically sealed container, the hermetically sealed container to contain a circuit board comprising an integrated circuit component, the lid comprising an inside surface of the hermetically sealed container; and
a base of a hermetically sealed container, the base to mate with the lid to form a hermetic seal,
wherein the lid comprises a plurality of fins, wherein individual fins of the plurality extend from an inside surface of the lid.

19. The system of claim 18, wherein the base is mated with the lid to form the hermetic seal.

20. The system of claim 19, further comprising a two-phase liquid coolant in the hermetically sealed container.

21. The system of claim 19, wherein the circuit board comprises one or more mezzanine connectors on a side of the circuit board opposite the integrated circuit component,
wherein the one or more mezzanine connectors are mated with a corresponding connector of a universal baseboard through one or more slots in the base.

22. The system of claim 19, further comprising one or more tubes extending into the hermetically sealed container to carry a second liquid coolant different from the liquid coolant through the hermetically sealed container.

23. A system comprising:
means for transferring heat from a integrated circuit component inside a hermetically sealed container to a lid of the hermetically sealed container; and
means for transferring heat from a lid of the hermetically sealed container.

24. The system of claim 23, wherein the means for transferring heat from the integrated circuit component comprise a two-phase coolant.

25. The system of claim 23, wherein the means for transferring heat from the lid of the hermetically sealed container comprises an immersion bath of a coolant different.
